(19) United States
(12) Patent Application Publication
(10) Pub. No.: US 2013/0005076 A1
(43) Pub. Date: Jan. 3, 2013

(54) THERMAL JET PRINTHEAD

(75) Inventor: Eliyahu Vronsky, Los Altos, CA (US)

(73) Assignee: KATEEVA, INC., Menlo Park, CA (US)

(21) Appl. No.: 13/172,750

(22) Filed: Jun. 29, 2011

(51) Int. Cl. C23C 16/448; H01L 51/56

(52) U.S. Cl. 438/99; 118/724; 257/E51.026

(57) ABSTRACT

Various aspects of the present teachings relate to film-forming apparatus and techniques wherein OLED film layers are deposited onto a substrate by thermal vaporization of substantially dry film-forming material from a thermal printhead. Embodiments are disclosed of a thermal printhead configured for operation very close to a substrate with reduced heating of the substrate.

### 1. FIELD

The present teachings relate to display technology; and to the production of films on substrates.

### 2. INTRODUCTION

Organic optoelectronic devices, such as organic light emitting diodes (OLEDs) used for flat-panel displays, can be fabricated by depositing layers of organic film onto a target substrate and coupling the top and bottom of the film stack to electrodes. High resolution OLED displays may require pixel characteristic dimensions on the order of 100 microns or less. To achieve the desired degree of quality control, the printhead gap, that is, the gap between the printhead and the target substrate, should be specified on an order of magnitude commensurate with the desired pixel characteristic dimensions. MEMS technology has been proposed for fabricating thermal printheads for evaporative deposition having this level of precision. However, for some configurations, such a small gap results in convective heating of the substrate by the printhead, which can negatively affect the under layer or the printed layer. The impact can range, for example, from degraded performance to complete destruction of the display device.

Thermal jet printing techniques that involve a diffusion process can be very sensitive to the print gap between the thermal jet printhead and the substrate. It is sometimes desirable to utilize as small a print gap as can practically be achieved in order to have, for example, good pixel definition and avoid cross pixel contamination. Printing with a flat printhead in close proximity to a substrate, however, can sometimes unduly heat up the substrate surface and cause damage, as just described (e.g., degraded performance or destruction to the under layer and/or printed layer, e.g., the EML layer). Often, when printing a pixilated RGB (Red, Green, Blue) display only ⅓ of the area is printed at a time; namely, the red (R), green (G) or blue (B) color. With high throughput printheads that present a flat surface to the substrate, the entire surface area of the substrate that confronts the printhead is heated up, as both pixel areas and non pixel areas on the printhead are heated to the same temperature during operation.

Thus, a problem to be solved, which is addressed by the present teachings, is how to provide a thermal printhead configured for operation very close to the substrate with reduced heating of the substrate.

### SUMMARY OF VARIOUS EMBODIMENTS

An exemplary and non-limiting summary of various embodiments is set forth next.

Various aspects of the present teachings relate to, among other things, thermal printheads adapted for operation very close to a substrate with reduced heating of the substrate. Instead of a flat printhead, various aspects of the present teachings provide a printhead structure comprising protrusions standing out of a body (e.g., a silicon body). In various embodiments, the protrusions can extend from a surface of the body, mirroring one color pixel.

In various aspects, the present teachings relate to a film-forming apparatus, comprising a transfer member including a first face; a plurality of protrusions extending from the first face, with each protrusion including a distal end, wherein the distal ends are disposed substantially along a common plane; a thermal insulation material interposed between adjacent protrusions; a vaporization site formed at each distal end, configured to receive and support a portion of a film-forming material in a carrier liquid; and one or more heaters adapted to heat each vaporization site; wherein, in operation, portions of film-forming material in carrier liquid that are received and supported at respective vaporization sites can be vaporized and thereby deposited as substantially dry film material on an adjacent substrate.

According to various embodiments, the distal ends include surface features selected from the group consisting of pores, channels, micro-pillars, coatings, and any combination of the foregoing.

Various embodiments further comprise a source of film-forming material in a carrier liquid, with the source being adapted for delivering portions of film-forming material in a carrier liquid to the vaporization sites.

In various embodiments, the source comprises, at least in part, one or more inkjet apparatus. In a variety of embodiments, the source includes a basin, and the transfer member is adapted for movement towards and away from the basin. In some embodiments, the source comprises a layer of liquid held by a carrier structure by way of capillary forces, and the transfer member is adapted for movement towards and away from the layer of liquid. In various embodiments, the source includes a rotatable drum adapted to traverse the transfer member, proximate the distal ends of the protrusions.

In a variety of embodiments, the one or more heaters are configured to heat the protrusions and vaporization sites through the first face of the transfer member.

A variety of embodiments further comprise a support upon which a substrate may be positioned for receiving substantially dry film material from the vaporization sites. A variety of embodiments further comprise a substrate positioned on the support, with the substrate having a first surface region that is substantially planar. In a variety of embodiments, the substrate and/or support comprise, at least in part, a heat sink.

Various embodiments further comprise a substrate positioned on the support, with the substrate having a first surface region that is substantially planar; and the transfer member is disposed so that the distal ends closely confront the first surface region, with a region separating each distal end and the first surface region defining a gap of less than 500 micrometers, less than 400 micrometers, less than 300 micrometers, less than 200 micrometers, less than 100 micrometers, less than 75 micrometers, less than 50 micrometers, less than 35 micrometers, less than 25 micrometers, less than 15 micrometers, and/or less than about 10 micrometers. In some embodiments, the gap is within a range of from about 10 micrometers to about 75 micrometers. In various embodiments, the gap is within a range of from about 20 micrometers to about 50 micrometers.

In some embodiments, the transfer member is movable between a plurality of positions, including a first position, adjacent the source, and a second position, adjacent the support. A variety of embodiments further comprise a rotatable drum, wherein the transfer member is mounted on the drum for movement between the positions.

In various embodiments of the apparatus, with the transfer member disposed in the second position, the distal ends closely confront the first surface region, with a region separating each distal end and the first surface region defining a gap of less than 500 micrometers, less than 400 micrometers, less than 300 micrometers, less than 200 micrometers, less than 100 micrometers, less than 75 micrometers, less than 50 micrometers, less than 35 micrometers, less than 25 micrometers, less than 15 micrometers, and/or less than about 10 micrometers. In some embodiments, the gap is within a range of from about 10 micrometers to about 75 micrometers. In various embodiments, the gap is within a range of from about 20 micrometers to about 50 micrometers.

According to various embodiments, the transfer member and the protrusions are monolithic.

In a number of embodiments, the transfer member and the protrusions are comprised, at least in part, of silicon.

According to a variety of embodiments, the thermal insulation material includes at least one gas. In various embodiments, the at least one gas comprises air, nitrogen, or a combination thereof.

In various of its aspects, the present teachings relates to a film-forming apparatus, comprising means for delivering a plurality of portions of a carrier liquid containing a film-forming material to a plurality of respective vaporization sites disposed along a common plane in spaced relation to one another; means for supporting the plurality of portions at the sites; means for thermally insulating each site from adjacent sites; means for vaporizing the carrier liquid, thereby substantially drying the film-forming material at the sites; means for vaporizing substantially dry film-forming material at the sites; and means for directing vaporized film-forming material to a substrate, whereby a substantially dry film can be formed.

In various embodiments, upon directing the vaporized film-forming material to a substrate, each of the sites is separated from the substrate by a distance of from about 10 micrometers to about 50 micrometers.

In a variety of embodiments, the means for thermally insulating includes at least one gaseous material (e.g., air, nitrogen, or a combination thereof).

Further aspects of the present teachings relate to a method for forming a film, comprising delivering a plurality of portions of a carrier liquid containing a film-forming material to a plurality of respective vaporization sites, wherein the sites are disposed along a common plane in spaced relation to one another; supporting the plurality of portions at the sites; thermally insulating each site from adjacent sites; heating the sites supporting the plurality of portions, thereby vaporizing the carrier liquid and substantially drying the film-forming material at the sites; vaporizing the substantially dry film-forming material; and depositing the vaporized film-forming material onto a substrate, whereby a substantially dry film is formed.

In various embodiments, the step of thermally insulating comprises disposing at least one gaseous material in regions separating adjacent sites.

A variety of embodiments further comprise moving the sites between a first position, whereat the step of delivering is performed, and a second position, whereat the step of depositing is performed.

According to various embodiments of the method, spaced-apart regions of the substrate are heated during the step of depositing, while intervening regions of the substrate, between the spaced-apart regions, are limited to a cooler temperature than the temperature reached by the spaced-apart regions.

In a variety of embodiments of the method, during the step of depositing, each of the sites is separated from the substrate by a distance of from about 10 micrometers to about 75 micrometers. In various embodiments, the distance is from about 20 micrometers to about 50 micrometers.

According to various embodiments, one or more of the steps of the method are performed at substantially atmospheric pressure. In some embodiments, all of the steps of the method are carried out at substantially atmospheric pressure.

### BRIEF DESCRIPTION OF THE DRAWINGS

Other systems, methods, features and advantages of the present teachings will be or will become further apparent to one with skill in the art upon examination of the following figures and description. Component parts shown in the drawings are not necessarily to scale, and may be exaggerated to better illustrate features of the present teachings. In the drawings, like reference numerals may designate like parts throughout the different views, wherein:

FIG. 1 schematically depicts a transfer member including a plurality of protrusions adjacent a substrate upon which red, green and blue films have been deposited; according to various embodiments of the present teachings;

FIG. 2 depicts a temperature profile of a glass substrate to be obtained using thermal printheads according to various embodiments of the present teachings, where it can be seen that the temperature of the glass is higher in the areas where end regions of protrusions of a transfer member come in close proximity to the glass surface, while the regions between adjacent protrusions are cooler;

FIG. 3 schematically illustrates an inkjet head supplying droplets of liquid containing film-forming material to distal-end regions of protrusions of a transfer member; according to various embodiments of the present teachings;

FIG. 4 schematically illustrates a rotatable drum supplying droplets of liquid containing film-forming material to distal-end regions of protrusions of a transfer member; according to various embodiments of the present teachings;

FIGS. 5A-B schematically depict a basin comprising a source of liquid containing film-forming material, with FIG. 5A showing the protrusions of a transfer member dipped into a liquid in the basin so that the distal end regions of the protrusions become wetted, and FIG. 5B showing, upon withdrawing the transfer member in the direction of arrow, the wetted distal end regions retain a portion of the liquid thereon; according to various embodiments of the present teachings;

FIGS. 6A-B schematically depict a source of liquid containing film-forming material with the source comprising a layer of liquid held by way of capillary forces in a carrier structure that includes a liquid source region; with FIG. 6A showing that upon moving the transfer member in the direction of the arrow, the protrusions of the transfer member can be dipped into the layer of liquid so that the distal end regions of the protrusions become wetted, and with FIG. 6B showing that upon withdrawing the transfer member in the direction of the arrow the wetted distal end regions can retain a portion of the liquid thereon; according to various embodiments of the present teachings; and,

FIG. 7 schematically illustrates a high-resolution transfer member including protrusions for red pixels, disposed in pixel integer gap, adjacent a substrate; according to various embodiments of the present teachings.

### DESCRIPTION

Various aspects of the present teachings relate to film-forming apparatus and techniques wherein OLED film layers are deposited onto a substrate by thermal vaporization of substantially dry film-forming material from a thermal printhead. According to various embodiments, a film-forming material, such as an organic ink material, can be dissolved or suspended in a liquid carrier to form a liquid ink. The ink can be transferred to the printhead, then the target substrate and printhead positioned into close proximity to one another. The ink can then be heated in stages. The first stage evaporates the carrier liquid. During the second stage, the ink can be heated at or above its vaporization temperature until the organic ink materials evaporate or sublimate to cause condensation of the organic vapor onto the target substrate. See, for example, US patent publication number US2008/0311307; incorporated herein by reference.

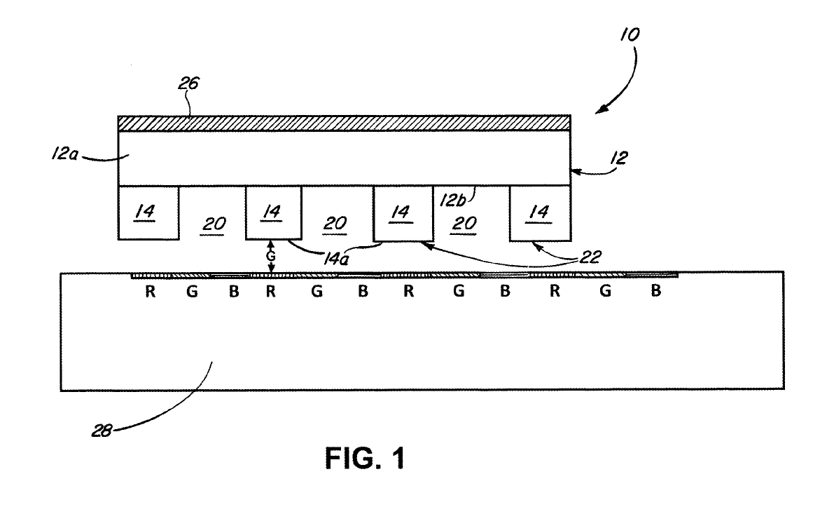

Referring now to the illustrative embodiment depicted in FIG. 1, a film-forming apparatus, denoted generally at 10, can comprise a printhead including a transfer member 12 having a body 12a and a first transfer face or transfer member 12b. A plurality of protrusions (also referred to as pillars, columns, rods, and the like), such as 14, can extend from the first face 12b, with each protrusion 14 including a distal-end region, such as 14a. In various embodiments, the distal ends 14a are disposed substantially along a common plane, in spaced relation to one another. A thermal insulation material can be interposed in the regions separating adjacent protrusions, indicated at 20. One or more vaporization sites, such as 22, can be located at each distal end 14a. In various embodiments, each vaporization site 22 is configured to receive and support a portion of a film-forming material in a carrier liquid. One or more heaters, such as 26, can be adapted to heat the vaporization sites 22.

Generally, in operation, portions of film-forming material in carrier liquid can be received and supported at respective vaporization sites 22. Employing one or more heaters, such as 26, carrier liquid can be evaporated away, and then dry film-forming material can be vaporized and directed to an adjacent substrate, such as glass substrate 28, thereby forming a substantially dry film material on the substrate. In FIG. 1, red, green, and blue pixels (denoted as R, G, and B, respectively) are shown as deposited films on substrate 28.

When heating up the silicon bulk of a transfer member, such as transfer member 12 shown in FIG. 1, most of the area of the transfer member is kept relatively far from the substrate, with only the protrusions getting into close proximity. The heat that the pillars transfer to the substrate is diffused in the substrate by the cold gaps, corresponding to regions 20, reducing the glass temperature. The insulating material (e.g., air or N2) between the protrusions provides thermal isolation of the bulk head or body from the substrate. It may be considered that cooler portions of the substrate act as a heat sink for absorbing, conducting, and/or transferring heat away from the hotter regions and dissipating the heat. Moreover, a support means for the substrate can facilitate the heat sink effect. The support can comprise, for example, one or more gases in motion (e.g., air bearings supporting the substrate) and/or one or more thermally conductive materials such as an aluminum alloy, copper, and/or ceramic material(s) supporting the substrate.

More generally, according to various embodiments, the film material can be delivered to the transfer member in the form of a solid ink, liquid ink, or gaseous vapor ink comprised of pure film material or film material and non-film (carrier) material. Using ink can be helpful because it can provide the film material to the transfer member with one or more non-film materials to facilitate handling of the film material prior to deposition onto the substrate. The film material can comprise an OLED material. The film material can comprise a mixture of multiple materials. The carrier material can comprise one or more materials. For example, the carrier can comprise a mixture of materials. An example of a liquid ink is film material dissolved or suspended in a carrier fluid or liquid. Another example of a liquid ink is pure film material in the liquid phase, such as film material that is liquid at the ambient system temperature or film material that is maintained at an elevated temperature so that the film material forms a liquid melt. An example of a solid ink is solid particles of film material. Another example of a solid ink is film material dispersed in a carrier solid. An example of a gas vapor ink is vaporized film material. Another example of a gaseous vapor ink is vaporized film material dispersed in a carrier gas. The ink can deposit on the transfer member as a liquid or a solid, and such phase can be the same or different than the phase of the ink during delivery. In one example, the film material can be delivered as gaseous vapor ink and deposit on the transfer member in the solid phase. In another example, the film material can be delivered as a liquid ink and deposit on the transfer member in the liquid phase. The ink can deposit on the transfer member in such a way that only the film material deposits and the carrier material does not deposit; the ink can also deposit in such a way that the film material as well as one or more of the carrier materials deposits.

In one example, the film material can be delivered as a gaseous vapor ink comprising both vaporized film material and a carrier gas, and only the film material deposits on the transfer member. In another example, the film material can be delivered as a liquid ink comprising film material and a carrier fluid, and both the film material and the carrier fluid deposit on the transfer member. In various embodiments, the film material delivery mechanism can deliver the film material onto the transfer member in a prescribed pattern. The delivery of film material can be performed with material contact or without material contact between the transfer member and the delivery mechanism.

The transfer member 12 can be constructed of any suitable material(s) using methods known to those skilled in the art. In various embodiments, the transfer member 12, including the protrusions 14, is monolithic. For example, the transfer member 12 and the protrusions 14 can be formed from a single piece of silicon. In other embodiments, the transfer member 12 and the protrusions 14 are made from separate materials, which are attached during a fabrication process. Microfabrication techniques can be used to form the body 12a of the transfer member 12 and the protrusions 14. The silicon can be microfabricated with other features, as well, such as surface features in the nature of pores, channels, micro-pillars, etc., for example, to assist in handling and/or positioning of organic carrier liquid containing one or more film-forming materials. See, for example, U.S. provisional patent application Ser. No. 61/453,098, entitled, “Method and Apparatus for Delivering Ink Material from a Discharge Nozzle”; incorporated herein by reference. A variety of microfabrication techniques can be employed, such as etching, bonding, and micromachining techniques. See, for example, Silicon Micromachining by Miko Elwenspoek and Henri V. Jansen, ISBN 0521607671, Cambridge, UK: Cambridge University Press, August 2004; incorporated herein by reference.

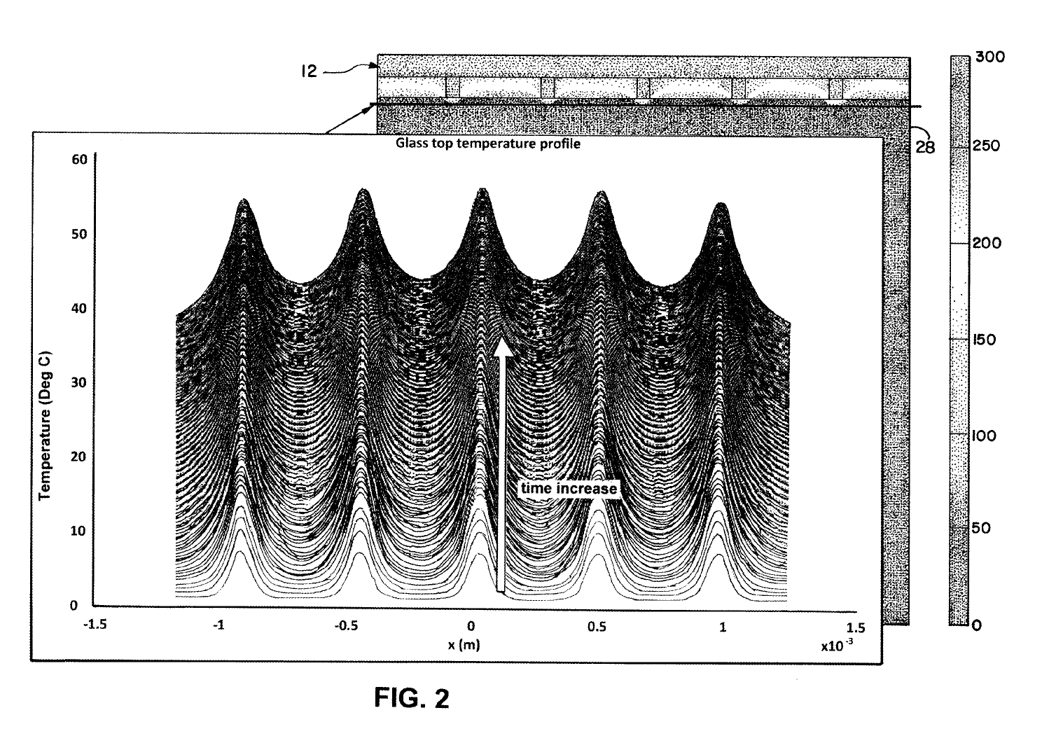

Thermal printheads of the present teachings, according to various aspects and embodiments disclosed herein, are adapted for operation in close proximity to a substrate, and can provide the advantage of reduced heating of the substrate. In this regard, attention is drawn to FIG. 2, which depicts a temperature profile of a glass substrate surface to be obtained using thermal printheads according to various embodiments of the present teachings. It can be seen that the temperature of the glass is higher in the areas where end regions of the protrusions of a transfer member come in close proximity to the glass surface, while the regions between adjacent protrusions are cooler.

In some embodiments, the transfer member is substantially stationary. In a variety of embodiments, the transfer member is movable. For example, in some embodiments, the transfer member can be movable between a plurality of positions, including a first position, adjacent the source, and a second position, adjacent the support. In some embodiments, the transfer member is movable to a third position, at a station configured for cleaning the printhead. In some embodiments, movement of the transfer member is facilitated by a rotatable drum, wherein the transfer member is mounted on the drum for movement between any of plural positions. In a variety of embodiments, a plurality of transfer members are mounted upon the same drum, thereby providing for very high throughput printing. In some embodiments, printheads of the present teachings are mounted upon facets which, in turn, are mounted to a rotatable drum. See, for example, U.S. patent application Ser. Nos. 12/954,910 and 61/473,646; incorporated herein by reference.

Various aspects of the present teachings provide means for delivering one or more portions of a carrier liquid containing a film-forming material to one or more vaporization sites. Such means can include, for example, a source of film-forming material in a carrier liquid. The source can be adapted for delivering portions of film-forming material in a carrier liquid to the vaporization sites. Several exemplary embodiments of means for delivering are described next.

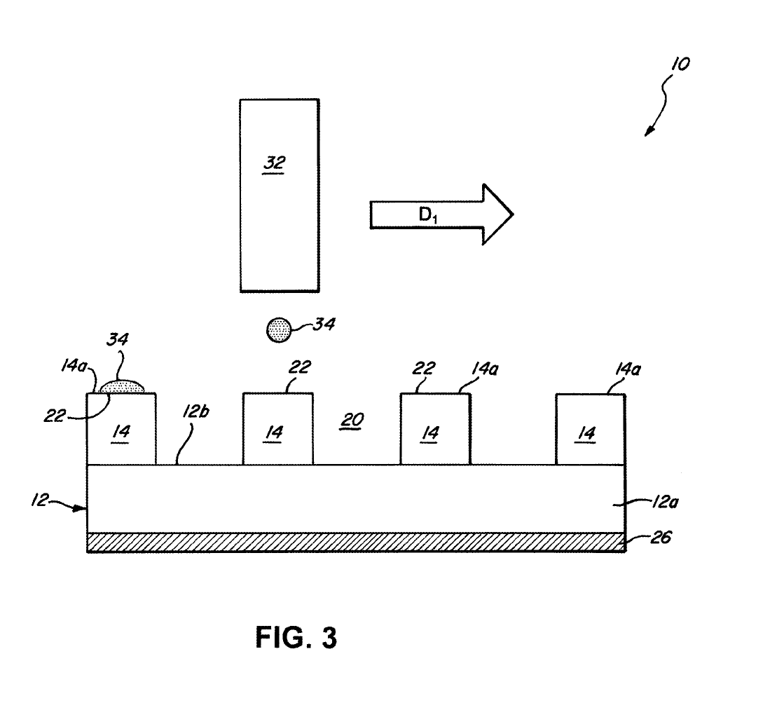

Loading of carrier liquid containing film-forming material, or ink, to the vaporization sites on the protrusions can be accomplished in a variety of ways. For example, in some embodiments, the source comprises, at least in part, one or more inkjet apparatus. See, for example, US patent publication numbers US2008/0311307 and US2010/0171780; incorporated herein by reference. Referring to FIG. 3, one or more inkjets, such as 32, can eject droplets of ink, depicted at 34, onto one or more vaporization sites, such as 22, in accordance with the present teachings. In the illustrated embodiment, inkjet head 32 is adapted for movement in the direction of arrow D₁ for travel across the transfer member 12, adjacent protrusions 14. Inkjet head 32 can deliver droplets of ink 34 to the vaporization sites 22 of transfer member 12.

Some embodiments contemplate the use of an ink transfer method such as gravure, flexo or offset to “print” over the protrusions. See, for example, Handbook on Printing Technology (Offset, Gravure, Flexo, Screen) 2nd edition, Author: NIIR, Board ISBN: 9788178330877; incorporated herein by reference.

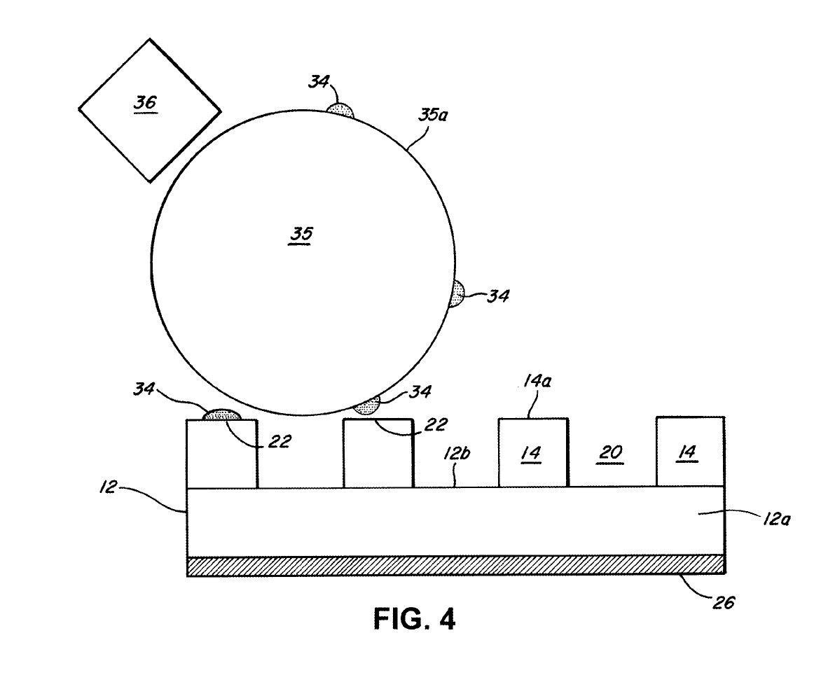

The exemplary embodiment of FIG. 4 shows a transfer drum 35 adapted to rotate about its central axis. An inking system is schematically depicted at 36, which is configured to intermittently supply ink to a surface of the drum as the drum 35 rotates, thereby creating spaced-apart droplets 34 on the drum surface 35a. The drum 35 can be configured so that surface tension forces assist in maintaining the position of the droplets 34 on the surface 35a. As the drum 35 translates in a direction across the transfer member 12, moving from one protrusion 14 to the next, the droplets 34 can be transferred from the drum surface 35a to the vaporization site(s) 22 of each of the protrusions 14.

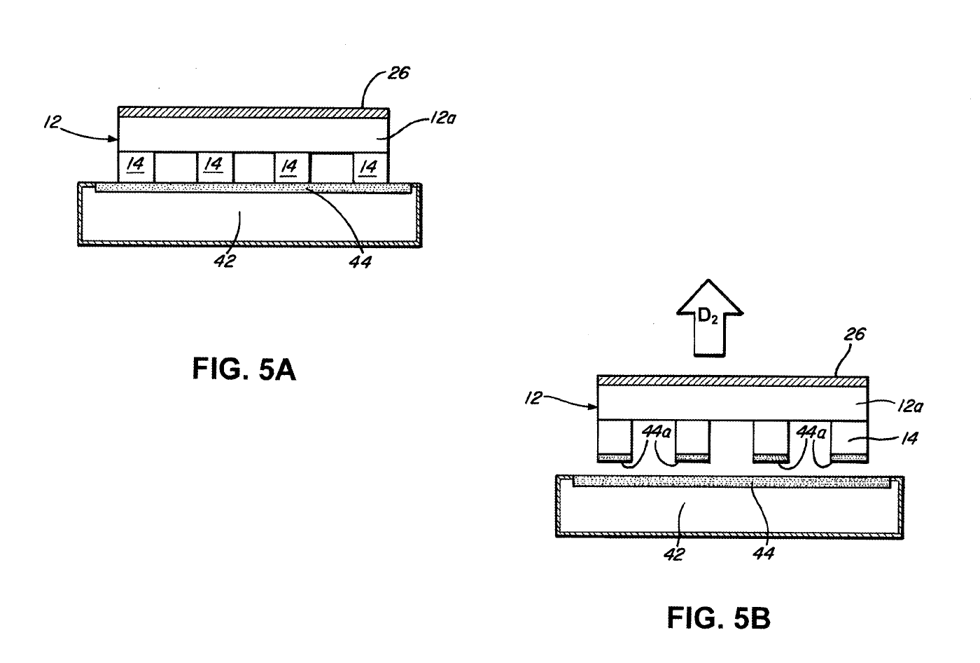

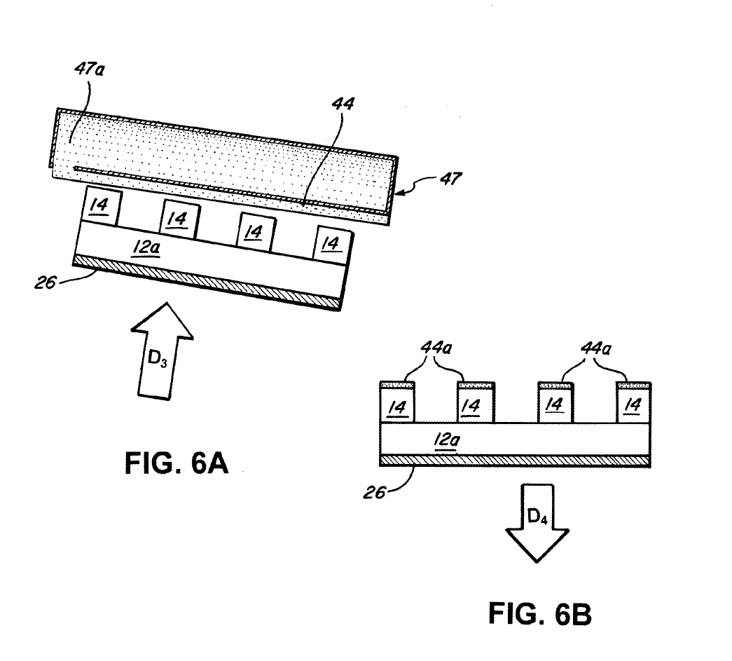

Various embodiments contemplate dipping the protrusions into a device holding a quantity of liquid ink. According to various embodiments, a small amount of liquid can be sufficient. In various embodiments, the dip can be done into a basin, such as basin 42 illustrated in FIGS. 5A-B, or into a layer of liquid held with capillary forces, such as shown in FIGS. 6A-B.

In the exemplary embodiment of FIGS. 5A-B, basin 42 provides a source of liquid containing film-forming material, denoted as 44. As shown in FIG. 5A, the protrusions 14 of transfer member 12 can be dipped into the liquid 44 in the basin 42 so that the distal end regions 14a of the protrusions 14 become wetted. Upon withdrawing the transfer member 12 in the direction of arrow D₂ of FIG. 5B, the wetted distal end regions 14a can retain a portion of the liquid thereon. In the illustrated embodiment, the retained liquid forms a substantially uniform film of liquid, denoted as 44a in FIG. 5B, across the distal end region 14a of each protrusion 14. The retained liquid 44a can take other configurations (i.e., other than a substantially uniform film), such as one or more droplets, one or more strips of film, or one or more linear or curved (e.g., serpentine) lines of liquid. The configuration assumed by the retained liquid 44a can depend on mechanical and/or chemical features of the protrusions 14 and their distal end regions 14a, such as described herein.

The exemplary embodiment of FIGS. 6A-B depicts a source of liquid containing film-forming material, denoted as 44, with the source comprising a layer of liquid held by way of capillary forces. A carrier structure 47, which has a liquid source region 47a, can hold the layer of liquid. As can be seen in FIG. 6A, upon moving the transfer member 12 in the direction of arrow D₃, the protrusions 14 of transfer member 12 can be dipped into the layer of liquid 44 so that the distal end regions 14a of the protrusions 14 become wetted. Upon withdrawing the transfer member 12 in the direction of arrow D₄ of FIG. 6B, the wetted distal end regions 14a can retain a portion of the liquid thereon. In the illustrated embodiment, and as with the just-described embodiment, the retained liquid forms a substantially uniform film of liquid, denoted as 44a in FIG. 6B, across the distal end region 14a of each protrusion 14. The retained liquid 44a can take other configurations (i.e., other than a substantially uniform film), such as one or more droplets, one or more stripes of film, or one or more linear or curved (e.g., serpentine) lines of liquid. As well, the configuration assumed by the retained liquid 44a can depend on mechanical and/or chemical features of the protrusions 14 and their distal end regions 14a, such as described herein.

In various embodiments, shifting means can be operatively connected to the transfer member for moving it along an axis, e.g., toward and away from a source of liquid containing film-forming material and/or toward and away from a substrate. The shifting means can comprise, for example, an actuator, such as a z-motion actuator adapted to move the transfer member in a linear or vertical fashion. In an exemplary arrangement, a solenoid assembly includes a solenoid piston movable between two positions. The lower end of the piston, in this embodiment, is connected to an upper portion of the transfer member. Upon activation, the piston is drawn downwardly (z direction), thereby shifting the transfer member to its lowered position. Upon release, the piston returns to its normal, raised position, e.g., under spring bias, thereby shifting the transfer member to its raised position.

Other devices, useful as shifting means, include, for example, pneumatic, hydraulic, magnetostrictive, and piezoelectric actuators, as well as motor assemblies (e.g., steppers) operable to generate a downward motive force followed by reciprocation.

In various embodiments, positioning means can be utilized to move the transfer member linearly or in an x-y plane to locate the transfer member at a selected position, e.g., a loading and/or deposition position. In one exemplary arrangement of the positioning means, the transfer member is carried on a movable arm or support that can be moved to a desired position and then, optionally, releasably clamped or locked down. Such positioning can be accomplished in a manual or automated fashion, as desired.

Exemplary automated devices useful for positioning include, for example, robots with electronically controlled linked or crossed movable arms, such as a SCARA, gantry and Cartesian robots. In some embodiments, an x-y positioning assembly is employed, comprising a motorized x-y carriage or rail arrangement. In other embodiments, the transfer head is threadedly mounted on a worm screw that can be driven (rotated) in a desired direction by a stepper motor, as directed by a control unit. It is understood, of course, that any other robotic mechanism could be used in accordance with the present teachings so long as it can accomplish substantially the same purposes and secure substantially the same result.

Various aspects of the present teachings relate to means for supporting a substrate. According to various embodiments, a support can be provided upon which a substrate can be positioned for receiving substantially dry film material from the vaporization sites. In certain embodiments, during a printing process, the substrate is supported by air bearings. In various embodiments, the substrate is disposed in a housing within which selected aspects of the environment can be controlled (e.g., gaseous environment, temperature, and/or pressure, etc.). In various embodiments, the substrate is acted upon in an environment comprising an inert gas, e.g., nitrogen, at atmospheric pressure. According to some embodiments, the substrate's location in relation to the housing can be controlled using a combination of air pressure and vacuum. See, for example, US patent publication number US2010/0201749; incorporated herein by reference. In some embodiments, the substrate can be transferred and positioned using one or more conveyor belts and/or robotics.

As previously described, a support means for the substrate can facilitate a heat sink effect. The support can comprise, for example, one or more gases in motion (e.g., air bearings supporting the substrate) and/or one or more thermally conductive materials such as an aluminum alloy, copper, and/or ceramic material(s) supporting the substrate.

Various aspects of the present teachings relate to means for receiving dried film material, whereby a film is formed. According to various embodiments, a substrate, such as glass (which may or may not include one or more film materials thereon), can be positioned on the support. The substrate can include at least one surface region that is substantially planar. In various embodiments, the entire (or substantially the entire, e.g., at least 70%, at least 80%, at least 90%, and/or at least 95%) substrate comprises a substantially planar square or rectangular piece of glass. With the transfer member disposed in the second position (i.e., adjacent to the support), the distal ends can closely confront a substantially planar surface region of the substrate. A region separating each distal end and the substantially planar surface region defines a small gap, denoted by the letter G in FIG. 1. Gap G can be, e.g., less than about 500 micrometers, less than about 400 micrometers, less than about 300 micrometers, less than about 200 micrometers, less than about 100 micrometers, less than about 75 micrometers, less than about 50 micrometers, less than about 35 micrometers, less than about 25 micrometers, less than about 15 micrometers, and/or less than about 10 micrometers. Gap G is also referred to as a print gap. In some embodiments, upon directing the vaporized film-forming material to a substrate, the gap is, for example, within a range of from about 10 micrometers to about 75 micrometers. In various embodiments, upon directing the vaporized film-forming material to a substrate, each of the sites is separated from the substrate by a distance of from about 10 micrometers to about 50 micrometers. In various embodiments, the gap can be, for example, within a range of from about 20 micrometers to about 50 micrometers. In certain embodiments, the gap is about 10, about 15, about 20, about 25, about 30, about 35, about 40, about 45, or about 50 micrometers.

Various aspects of the present teachings relate to means for thermally insulating each site from adjacent sites. In various embodiments, the means for thermally insulating includes at least one thermal insulation material in the regions separating adjacent vaporization sites, such as regions 20 shown in FIG. 1. In various embodiments, the thermal insulation material includes at least one gas. For example, some embodiments contemplate the use of air, nitrogen, or a combination thereof. In certain embodiments, the insulation material consists essentially of nitrogen.

Various aspects of the present teachings relate to means for vaporizing the carrier liquid, thereby substantially drying the film-forming material at the vaporization sites. As well, various aspects relate to means for vaporizing substantially dry film-forming material at the sites. In this regard, heating structure can be provided proximate or at each vaporization site. The heating structure can comprise, for example, a heater such as a thin film heater (FIG. 1; heater 26), wire element heater, or other suitable heater. In the embodiment of FIG. 1, heater 26 can heat protrusions 14 and their respective vaporization site(s) through first surface 12b of transfer member 12.

Various aspects of the present teachings relate to means for directing vaporized film-forming material to a substrate, whereby a substantially dry film can be formed. In various embodiments, substantially dry film-forming material is disposed at the vaporization site(s). The site(s) are heated at or above the vaporization temperature of the material, thereby causing the material to vaporize or evaporate, with the resulting vapor condensing onto the target substrate. The vaporization sites can comprise, for example, pores open at both ends, blind pores, channel structure (e.g., serpentine or linear), and/or micro-pillars (e.g., disposed in an array) or similar microstructures.

The dimensions, e.g., height, width, and pitch, of the protrusions can be selected for desired performance characteristics. In some embodiments, protrusion heights can be, for example, from about 50 to about 200 micrometers (um), and the protrusion width from about 50 to about 100 um, and the pitch between adjacent protrusions from about 150 to about 600 um.

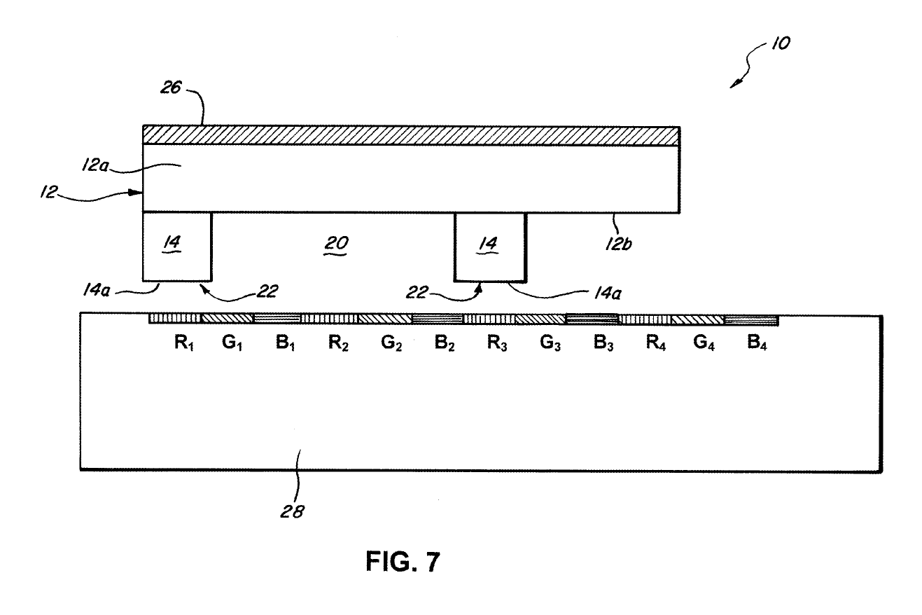

In the case of high resolution displays, the overall pixel size can be small and the protrusion pitch, as well. In these cases, a configuration wherein the protrusions are close together can increase the glass temperature over a set limit. To avoid this, the configuration of the protrusions can be designed to have the protrusions in pixel integer gap to keep the temperature of the glass within the limit. See, for example, FIG. 7, wherein two adjacent protrusions 14 are aligned, respectively, with pixels R₁ and R₃.

The size of the protrusions can be less than or greater than the pixel size. The size of the protrusions can depend, as well, on the ink loading method being used. The end region of the protrusions can be flat or contoured, for example, with pores, channels (line or serpentine), an array of micro pillars, etc. In some embodiments, another option is to utilize a wetting or non-wetting coating or treatment on the upper end region surface, such as, e.g., silicon and/or silicon oxide. Such mechanical and chemical features are designed to guide and hold the ink onto the preferred location(s) on the protrusions. In various embodiments, the preferred locations comprise the places where it is desired for the ink to dry in order to create a uniform print.

In some embodiments, a technique to help control the ink location comprises heating up the protrusions to a temperature that, with the appropriate combination of wetting properties of the ink, will result the desired spreading over the end regions of the protrusions.

Various aspects of the present teachings provide methods for forming a film. In various embodiments, for example, a method of the present teachings can comprise: delivering a plurality of portions of a carrier liquid containing a film-forming material to a plurality of respective vaporization sites, wherein the sites are disposed along a common plane in spaced relation to one another; supporting the plurality of portions at the sites; thermally insulating each site from adjacent sites; heating the sites supporting the plurality of portions, thereby vaporizing the carrier liquid and substantially drying the film-forming material at the sites; vaporizing the substantially dry film-forming material; and depositing the vaporized film-forming material onto a substrate, whereby a substantially dry film is formed.

In various embodiments, the step of thermally insulating comprises disposing at least one gaseous material, such as air, nitrogen, or a combination, in regions separating adjacent sites.

In some embodiments, the method further comprises moving the sites between a first position, whereat the step of delivering is performed, and a second position, whereat the step of depositing is performed. Some embodiments include movement to a third position, where the printhead can be cleaned or otherwise serviced.

In various embodiments, spaced-apart regions of the substrate are heated by the heated transfer member during the step of depositing, while intervening regions of the substrate, between the heated spaced-apart regions, do not reach as high a temperature as that reached by the heated spaced-apart regions. The intervening regions can be limited to a cooler temperature than the temperature reached by the heated spaced-apart regions.

Aspects of the present teachings can be practiced, for example, in connection with the teachings of US patent publication numbers US2008/0311307, US2006/0115585, US2010/0188457, US2011/0008541, US2010/0171780, and US2010/0201749, as well as U.S. patent application Ser. No. 12/954,910, Ser. No. 61/439,816, Ser. No. 61/453,098, Ser. No. 61/473,646, and Ser. No. 61/480,327; each incorporated herein by reference.

While the principles of the present teachings have been illustrated in relation to various exemplary embodiments shown and described herein, the principles of the present teachings are not limited thereto and include any modifications, alternatives, variations and/or equivalents thereof.

1. A film-forming apparatus, comprising:
a transfer member including a first face;
a plurality of protrusions extending from the first face, with each protrusion including a distal end; wherein the distal ends are disposed substantially along a common plane;
a thermal insulation material interposed between adjacent protrusions;
a vaporization site formed at each distal end, configured to receive and support a portion of a film-forming material in a carrier liquid; and
one or more heaters adapted to heat each vaporization site;
wherein, in operation, portions of film-forming material in carrier liquid that are received and supported at respective vaporization sites can be vaporized and thereby deposited as substantially dry film material on an adjacent substrate.

2. The apparatus of claim 1, wherein the distal ends include surface features selected from the group consisting of pores, channels, micro-pillars, coatings, and any combination of the foregoing.

3. The apparatus of claim 1, further comprising a source of film-forming material in a carrier liquid, with the source being adapted for delivering portions of film-forming material in a carrier liquid to the vaporization sites.

4. The apparatus of claim 3, wherein the source comprises, at least in part, one or more inkjet apparatus.

5. The apparatus of claim 3, wherein the source includes a basin, and wherein the transfer member is adapted for movement towards and away from the basin.

6. The apparatus of claim 3, wherein the source comprises a layer of liquid held by a carrier structure by way of capillary forces, and wherein the transfer member is adapted for movement towards and away from the layer of liquid.

7. The apparatus of claim 3, wherein the source includes a rotatable drum adapted to traverse the transfer member, proximate the distal ends of the protrusions.

8. The apparatus of claim 1, wherein said one or more heaters are configured to heat the protrusions and vaporization sites through the first face of the transfer member.

9. The apparatus of claim 3, further comprising a support upon which a substrate may be positioned for receiving substantially dry film material from the vaporization sites.

10. The apparatus of claim 9, further comprising a substrate positioned on said support, with the substrate having a first surface region that is substantially planar; and wherein the transfer member is disposed so that the distal ends closely confront the first surface region, with a region separating each distal end and the first surface region defining a gap of less than 500 micrometers.

11. The apparatus of claim 9, wherein the transfer member is movable between a plurality of positions, including a first position, adjacent the source, and a second position, adjacent the support.

12. The apparatus of claim 11, further comprising a rotatable drum, wherein the transfer member is mounted on said drum for movement between the plurality of positions.

13. The apparatus of claim 11, further comprising a substrate positioned on said support, with the substrate having a first surface region that is substantially planar.

14. The apparatus of claim 13, wherein, with the transfer member disposed in the second position, the distal ends closely confront the first surface region, with a region separating each distal end and the first surface region defining a gap of less than 500 micrometers.

15. The apparatus of claim 14, wherein the gap is within a range of from about 10 micrometers to about 75 micrometers.

16. The apparatus of claim 15, wherein the gap is within a range of from about 20 micrometers to about 50 micrometers.

17. The apparatus of claim 1, wherein the transfer member and the protrusions are monolithic.

18. The apparatus of claim 17, wherein the transfer member and the protrusions are comprised, at least in part, of silicon.

19. The apparatus of claim 1, wherein the thermal insulation material includes at least one gas.

20. The apparatus of claim 19, where the at least one gas comprises air, nitrogen, or a combination thereof.

21. A film-forming apparatus, comprising:
means for delivering a plurality of portions of a carrier liquid containing a film-forming material to a plurality of respective vaporization sites disposed along a common plane in spaced relation to one another;
means for supporting the plurality of portions at the sites;
means for thermally insulating each site from adjacent sites;
means for vaporizing the carrier liquid, thereby substantially drying the film-forming material at the sites;
means for vaporizing substantially dry film-forming material at the sites; and
means for directing vaporized film-forming material to a substrate, whereby a substantially dry film can be formed.

22. The apparatus of claim 21, wherein, upon directing the vaporized film-forming material to a substrate, each of the sites is separated from the substrate by a distance of from about 10 micrometers to about 50 micrometers.

23. The apparatus of claim 21, wherein the means for thermally insulating includes at least one gaseous material.

24. A method for forming a film, comprising:
delivering a plurality of portions of a carrier liquid containing a film-forming material to a plurality of respective vaporization sites, wherein the sites are disposed along a common plane in spaced relation to one another;
supporting the plurality of portions at the sites;
thermally insulating each site from adjacent sites;
heating the sites supporting the plurality of portions, thereby vaporizing the carrier liquid and substantially drying the film-forming material at the sites;
vaporizing the substantially dry film-forming material; and
depositing the vaporized film-forming material onto a substrate, whereby a substantially dry film is formed.

25. The method of claim 24, wherein the step of thermally insulating comprises disposing at least one gaseous material in regions separating adjacent sites.

26. The method of claim 24, further comprising moving the sites between a first position, whereat the step of delivering is performed, and a second position, whereat the step of depositing is performed.

27. The method of claim 24, wherein spaced-apart regions of the substrate are heated during the step of depositing, while intervening regions of the substrate, between the spaced-apart regions, are limited to a cooler temperature than the temperature reached by the spaced-apart regions.

28. The method of claim 27, wherein during the step of depositing, each of the sites is separated from the substrate by a distance of from about 10 micrometers to about 75 micrometers.

29. The method of claim 28, wherein the distance is from about 20 micrometers to about 50 micrometers.

30. The method of claim 24, wherein the steps are performed at substantially atmospheric pressure.
